(19) United States
(12) Patent Application Publication
(10) Pub. No.: US 2026/0173480 A1
(43) Pub. Date: Jun. 18, 2026

(54) SEMICONDUCTOR DEVICE, METHOD FOR MANUFACTURING THE SAME AND METHOD FOR MEASURING ELECTRICAL CHARACTERISTICS OF THE SAME

(71) Applicant: SAMSUNG ELECTRONICS CO., LTD., Suwon-si (KR)

(72) Inventors: Hoyeong JEONG, Suwon-si (KR); INHYUN SONG, Suwon-si (KR); SEOKJUN WON, Suwon-si (KR); BORAM LEE, Suwon-si (KR); WANGKYU LIM, Suwon-si (KR); Myungjin CHUNG, Suwon-si (KR); SUHAENG HEO, Suwon-si (KR)

(73) Assignee: SAMSUNG ELECTRONICS CO., LTD., Suwon-si (KR)

(21) Appl. No.: 19/282,672

(22) Filed: Jul. 28, 2025

(30) Foreign Application Priority Data
Dec. 12, 2024 (KR) 10-2024-0184864
Jan. 22, 2025 (KR) 10-2025-0009497

(51) Int. Cl. H10D 64/23; H01L 23/528; H10D 30/00

(52) U.S. Cl. CPC H10D 64/254; H10W 20/427; H10D 30/501

(57) ABSTRACT

A semiconductor device includes a power transfer network layer on a lower surface of a substrate, a source/drain pattern being on the substrate, and including a first pattern and a second pattern spaced apart from each other in a first direction parallel to an upper surface of the substrate, a backside power rail extending along the first direction under the source/drain pattern, a backside conductive structure between the backside power rail and the first pattern of the source/drain pattern, an active contact on an upper surface of the second pattern of the source/drain pattern, a first interlayered insulating layer covering an upper surface of the source/drain pattern, and a conductive pad penetrating the first interlayered insulating layer along a direction vertical to the first direction, and connected to the backside power rail. The active contact is shifted from the first pattern of the source/drain pattern in the first direction.

### CROSS-REFERENCE TO RELATED APPLICATIONS

This U.S. non-provisional patent application is based on and claims priority under 35 U.S.C. § 119 of Korean Patent Application Nos. 10-2024-0184864, filed on Dec. 12, 2024, and 10-2025-0009497, filed on Jan. 22, 2025, the disclosures of which are hereby incorporated by reference in their entireties.

### BACKGROUND

The present disclosure herein relates to a semiconductor device, a method for manufacturing the same, and a method for measuring electrical characteristics of the same, and more particularly, to a semiconductor device including a field effect transistor, a method for manufacturing the same, and a method for measuring electrical characteristics of the same.

A semiconductor device includes an integrated circuit including metal-oxide-semiconductor field effect transistors (MOSFETs). As a size and a design rule of the semiconductor device are gradually decreasing, scaling down of the metal-oxide-semiconductor field effect transistors is also gradually being accelerated. As the metal-oxide-semiconductor field effect transistors are gradually scaled down, operation characteristics of the semiconductor device may be deteriorated. Accordingly, research on various methods for overcoming limitation caused by high-integration of the semiconductor device and forming the semiconductor device with improved performance is being conducted.

### SUMMARY

The present disclosure provides a semiconductor device with improved analysis reliability for electrical characteristics, a method for manufacturing the same, and a method for measuring the electrical characteristics.

A technical goal of the disclosure is not limited to the goal mentioned above, and other technical goals that are not mentioned may be clearly understood from description below by those skilled in the art.

According to an aspect of an example embodiment of the disclosure, there is provided a semiconductor device including: a power transfer network layer on a lower surface of a substrate, a source/drain pattern being on the substrate, and including a first pattern and a second pattern spaced apart from each other in a first direction parallel to an upper surface of the substrate, a backside power rail extending along the first direction under the source/drain pattern, a backside conductive structure between the backside power rail and the first pattern of the source/drain pattern, an active contact on an upper surface of the second pattern of the source/drain pattern, a first interlayered insulating layer covering an upper surface of the source/drain pattern, and a conductive pad penetrating the first interlayered insulating layer along a direction vertical to the upper surface of the substrate, and connected to the backside power rail, wherein the active contact is shifted from the first pattern of the source/drain pattern in the first direction.

According to an aspect of an example embodiment of the disclosure, a semiconductor device includes a power transfer network layer on a lower surface of a substrate, a source/drain pattern being on the substrate, and including a first pattern and a second pattern spaced apart from each other in a first direction parallel to an upper surface of the substrate, a backside power rail extending along the first direction under the source/drain pattern, a backside conductive structure between the backside power rail and the first pattern of the source/drain pattern, an active contact on an upper surface of the second pattern of the source/drain pattern, a first interlayered insulating layer covering an upper surface of the source/drain pattern, and a conductive pad penetrating the first interlayered insulating layer along a direction vertical to the upper surface of the substrate, and connected to the backside power rail, wherein the active contact is shifted from the backside conductive structure in the first direction.

According to an aspect of an example embodiment of the disclosure, a semiconductor device includes a power transfer network layer on a lower surface of a substrate, a source/drain pattern on the substrate, a backside power rail extending under the source/drain pattern along a first direction parallel to an upper surface of the substrate, a backside conductive structure between the backside power rail and the source/drain pattern, an interlayered insulating layer covering an upper surface of the source/drain pattern, and a conductive pad penetrating the interlayered insulating layer along a direction vertical to the upper surface of the substrate, and connected to the backside power rail, wherein an upper surface of the conductive pad is not in contact with a conductive pattern including a conductive material.

According to an aspect of an example embodiment of the disclosure, a method for manufacturing a semiconductor device includes forming a measurement transistor on a semiconductor substrate, forming an interlayered insulating layer covering the measurement transistor, forming an active contact connected to the measurement transistor, forming a substrate instead of the semiconductor substrate, forming a backside conductive structure penetrating the substrate and connected to the measurement transistor, forming a backside power rail under the backside conductive structure, forming a conductive pad penetrating the interlayered insulating layer and the substrate to be connected to the backside power rail, and analyzing electrical characteristics of the measurement transistor by applying a first voltage to the conductive pad and applying a second voltage to the active contact.

In an embodiment, the first voltage may be a ground voltage.

In an embodiment, the applying of the first voltage to the conductive pad may include applying the first voltage to the conductive pad through a probe that is in contact with an upper surface of the conductive pad.

In an embodiment, the applying of the second voltage to the active contact may include applying the second voltage to the active contact through a probe that is in contact with an upper surface of the active contact.

In an embodiment, the method may further include forming metal patterns alternately disposed on the active contact, wherein the applying of the second voltage to the active contact may include applying the second voltage to a metal pattern and the active contact through a probe that is in contact with the metal pattern connected to the active contact among the metal patterns.

In an embodiment, the measurement transistor may include a first pattern, of a source/drain pattern, and a second pattern, of the source/drain pattern, that are adjacent to each other, a channel pattern between the first pattern and the second pattern of the source/drain pattern, and a gate electrode crossing the channel pattern, wherein the conductive pad may be connected to the first pattern of the source/drain pattern through the backside power rail and the backside conductive structure, and the active contact may be connected to the second pattern of the source/drain pattern.

According to an aspect of an example embodiment of the disclosure, a method for manufacturing a semiconductor device includes forming a measurement transistor on a semiconductor substrate, forming an interlayered insulating layer covering the measurement transistor, forming an active contact connected to the measurement transistor, forming metal patterns on the active contact, forming a substrate instead of the semiconductor substrate, forming a backside conductive structure penetrating the substrate and connected to the measurement transistor, forming a conductive pad penetrating at least any one metal pattern of the metal patterns, the interlayered insulating layer and the substrate, and analyzing electrical characteristics of the measurement transistor by applying a first voltage to the conductive pad and applying a second voltage to the backside conductive structure.

In an embodiment, the first voltage may be a ground voltage.

In an embodiment, the applying of the first voltage to the conductive pad may include applying the first voltage to the conductive pad through a probe that is in contact with a lower surface of the conductive pad.

In an embodiment, the applying of the second voltage to the backside conductive structure may include applying the second voltage to the backside conductive structure through a probe that is in contact with a lower surface of the backside conductive structure.

### BRIEF DESCRIPTION OF FIGURES

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a plan view illustrating a semiconductor device according to some embodiments of the disclosure;

FIGS. 2 and 3 are cross-sectional views taken along line A-A′ of FIG. 1, according to some embodiments of the disclosure;

FIG. 4 is a block diagram illustrating a semiconductor device including a circuit of a measurement transistor and peripheral components connected to the measurement transistor, according to some embodiments of the disclosure;

FIG. 5 is a cross-sectional view corresponding to line A-A′ of FIG. 1;

FIGS. 6, 7 and 8 are plan views illustrating a semiconductor device according to some embodiments of the disclosure, respectively;

FIGS. 9 to 14 are diagrams for explaining a method for manufacturing a semiconductor device according to some embodiments of the disclosure;

FIG. 15 is a diagram for explaining a method for manufacturing a semiconductor device according to some embodiments of the disclosure;

FIGS. 16 and 17 are diagrams for explaining a method for manufacturing a semiconductor device according to some embodiments of the disclosure;

FIG. 18 is a block diagram illustrating a semiconductor device including a circuit of a measurement transistor and peripheral components connected to the measurement transistor, according to some embodiments of the disclosure;

FIG. 19 is a cross-sectional view corresponding to line A-A′ of FIG. 1;

FIG. 20 is a block diagram illustrating a semiconductor device including a circuit of a measurement transistor and peripheral components connected to the measurement transistor, according to some embodiments of the disclosure;

FIG. 21 is a cross-sectional view corresponding to line A-A′ of FIG. 1;

FIG. 22 is a plan view illustrating a semiconductor device according to some embodiments of the disclosure; and

FIG. 23 is cross-sectional views corresponding to line A-A′ of FIG. 22.

### DETAILED DESCRIPTION

Hereinafter, example embodiments according to the disclosure will be described with reference to the accompanying drawings in more detail in order to more specifically describe the disclosure.

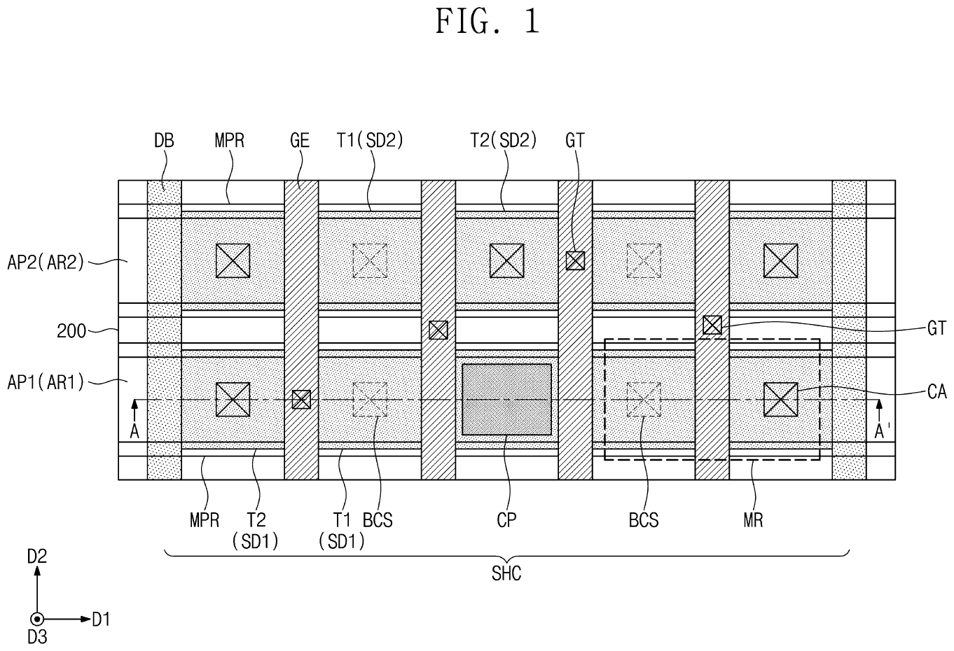

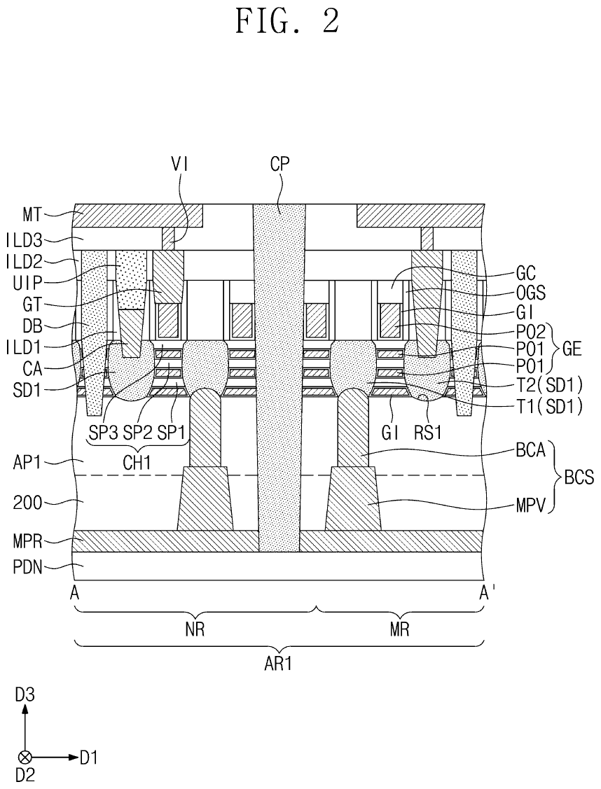

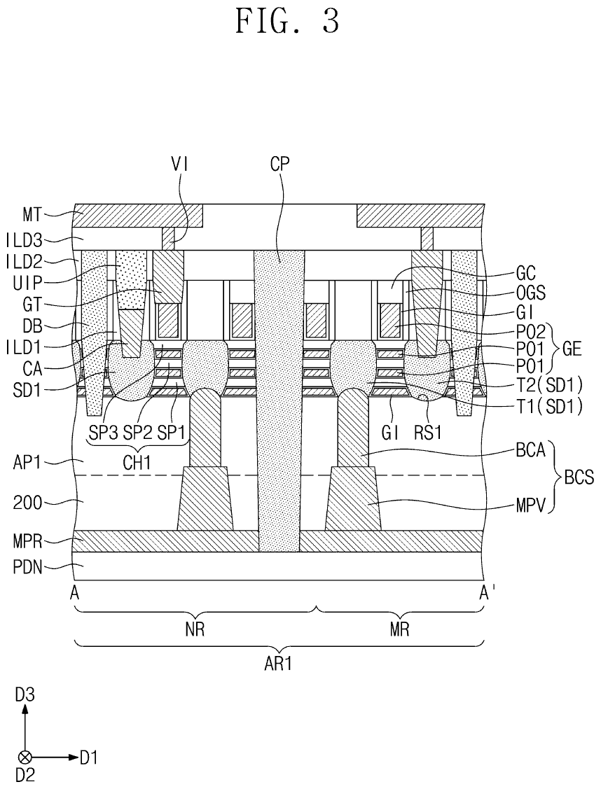

FIG. 1 is a plan view illustrating a semiconductor device according to some embodiments of the disclosure. FIGS. 2 and 3 are cross-sectional views corresponding to line A-A′ of FIG. 1, according to some embodiments of the disclosure.

Referring to FIGS. 1 and 2, a substrate 200 including a single height cell SHC may be provided. For example, the substrate 200 may be an insulating substrate. For example, the substrate 200 may include at least one of a silicon oxide (SiO₂) layer, a silicon nitride (SiN) layer or a silicon oxynitride (SiON) layer. In the present specification, each of the wordings, “A or B”, “at least one of A and B”, “at least one of A or B”, “A, B or C”, “at least one of A, B and C” and “at least one of A, B or C” may include any one of items listed together in a corresponding wording among the wordings, or all possible combinations thereof. For example, an expression “at least one of A and B” should be understood as including only A, only B, or both A and B.

The single height cell SHC may constitute one logic cell. In the present specification, the logic cell may mean a logic device (for example, AND, OR, XOR, XNOR, an inverter, or the like) that performs a specific function. That is, the logic cell may include transistors for constituting the logic device, and wires that connect the transistors each other.

The single height cell SHC may include a first active region AR1 and a second active region AR2 on the substrate 200. The first and second active regions AR1 and AR2 may respectively extend in a first direction D1, and may be spaced apart from each other in a second direction D2. The first and second directions D1 and D2 may be parallel to an upper surface of the substrate 200, and may cross each other. For example, the first active region AR1 may be a PMOSFET region, and the second active region AR2 may be an NMOSFET region.

A first active pattern AP1 may be provided in the first active region AR1. A second active pattern AP2 may be provided in the second active region AR2. Each of the first and second active patterns AP1 and AP2 may be defined by a trench TR on the substrate 200. The first and second active patterns AP1 and AP2 may be provided on the substrate 200. For example, the first and second active patterns AP1 and AP2 may protrude from the upper surface of the substrate 200 in a third direction D3. The third direction D3 may be a direction vertical to the upper surface of the substrate 200. The first active pattern AP1 may include a plurality of first active patterns AP1 spaced apart from each other along the first direction D1. The second active patterns AP2 may include a plurality of second active patterns AP2 spaced apart from each other along the second direction D2. For example, each of the first active pattern AP1 and the second active pattern AP2 may include at least one of silicon (Si), germanium (Ge) or silicon-germanium (SiGe). For another example, each of the first active pattern AP1 and the second active pattern AP2 may include an insulating material. For another example, each of the first active pattern AP1 and the second active pattern AP2 may include an insulating material and at least one of the semiconductor materials (Si, Ge and SiGe) described above.

An element separation pattern (not shown) may be provided on the substrate 200, and may fill the trench TR. The element separation pattern may surround the first active patterns AP1 and the second active patterns AP2. The element separation pattern may include an insulating material.

A first channel pattern CH1 may be provided on the first active pattern AP1, and a second channel pattern (not shown) may be provided on the second active pattern AP2. The first channel pattern CH1 may be provided in plurality, and the first channel patterns CH1 may be spaced apart from each other in the first direction D1. The second channel pattern may be provided in plurality, and the second channel patterns may be spaced apart from each other in the first direction D1. Each of the first channel pattern CH1 and the second channel pattern may include a first semiconductor pattern SP1, a second semiconductor pattern SP2 and a third semiconductor pattern SP3 stacked spaced apart from each other in the third direction D3, but an embodiment of the disclosure is not limited thereto. For example, each of the first channel pattern CH1 and the second channel pattern may include at least four semiconductor patterns. For example, each of the first to third semiconductor patterns SP1, SP2, and SP3 may include crystalline silicon.

First recesses RS1 may be defined between the first channel patterns CH1 adjacent to each other in the first direction D1. Second recesses (not shown) may be defined between the second channel patterns adjacent to each other in the first direction D1.

A first source/drain pattern SD1 may be provided on the first active pattern AP1, and a second source/drain pattern SD2 may be provided on the second active pattern AP2. The first source/drain pattern SD1 may fill the first recess RS1, and the second source/drain pattern SD2 may fill the second recess. Each of the first source/drain pattern SD1 and the second source/drain pattern SD2 may be connected to the first to third semiconductor patterns SP1, SP2, and SP3.

The first source/drain patterns SD1 may be impurity regions having a first conductive type (for example, a P-type), and the second source/drain patterns SD2 may be impurity regions having a second conductive type (for example, an N-type). For example, a pair of the first source/drain patterns SD1 adjacent to each other in the first direction D1 may be connected to each other through the first channel pattern CH1. For example, a pair of the second source/drain patterns SD2 adjacent to each other in the first direction D1 may be connected to each other through the second channel pattern.

The first source/drain patterns SD1 may include a semiconductor element (for example, SiGe) having a greater lattice parameter than a semiconductor element of the first channel pattern CH1. The second source/drain patterns SD2 may include the same semiconductor element (for example, Si) as that of the second channel pattern.

Each of the first source/drain pattern SD1 and the second source/drain pattern SD2 may include a first pattern T1 vertically overlapping a backside conductive structure BCS to be described later and a second pattern T2 vertically overlapping an active contact CA to be described later.

The first pattern T1 of each of the first source/drain pattern SD1 and the second source/drain pattern SD2 may not vertically overlap the active contact CA. In other words, the active contact CA may be shifted from the first pattern T1 of each of the first source/drain pattern SD1 and the second source/drain pattern SD2 in the first direction D1 or in an opposite direction of the first direction D1.

A gate electrode GE may be provided on each of the first channel pattern CH1 and the second channel pattern, and may cross each of the first channel pattern CH1 and the second channel pattern. The gate electrode GE may be provided in plurality. The gate electrodes GE may each extend in the second direction D2, and may be spaced apart from each other in the first direction D1.

The gate electrode GE may include an inner electrode PO1 and an outer electrode PO2. The inner electrode PO1 of the gate electrode GE may be provided between the first and second active patterns AP1 and AP2 and an uppermost semiconductor pattern SP3 among the first to third semiconductor patterns SP1, SP2, and SP3. The outer electrode PO2 of the gate electrode GE may be provided on the uppermost semiconductor pattern SP3. For example, the inner electrode PO1 of the gate electrode GE may include three electrode portions, but an embodiment of the disclosure is not limited thereto. For example, the inner electrode PO1 of the gate electrode GE may include four or more electrode portions.

The gate electrode GE may include a first metal pattern and a second metal pattern on the first metal pattern. The first metal pattern may include a work-function metal that controls a threshold voltage of a transistor. For example, the first metal pattern may include at least one of a metal material (for example, Ti, Mo, W, Cu, Al, Ta, Ru, Ir, Co, or the like) or metal nitride (for example, nitride of Ti, Mo, W, Cu, Al, Ta, Ru, Ir, Co, or the like). For example, the first metal pattern may further include carbon (C). For example, the first metal pattern may include metal materials having different work-functions.

For example, the second metal pattern may include a metal material (for example, Ti, Mo, W, Cu, Al, Ta, Ru, Ir, Co, or the like) having lower resistance than that of the first metal pattern.

For example, the inner electrode PO1 of the gate electrode GE may include the first metal pattern. For example, the outer electrode PO2 of the gate electrode GE may include the first metal pattern and the second metal pattern.

A gate capping pattern GC may be provided on an upper surface of the gate electrode GE. For example, the gate capping pattern GC may include at least one of SiON, SiCN, SiOCN or SiN.

External gate spacers OGS may be provided on side surfaces of the outer electrode PO2 of the gate electrode GE, and may respectively extend onto side surfaces of the gate capping pattern GC. The external gate spacer OGS may include a single layer or a composite layer. For example, the external gate spacer OGS may include at least one of SiON, SiCN, SiOCN or SiN.

A gate insulating pattern GI may be interposed between the gate electrode GE and the first to third semiconductor patterns SP1, SP2, and SP3. The gate insulating pattern GI may cover an upper surface, a lower surface and both side surfaces of each of the first to third semiconductor patterns SP1, SP2, and SP3. The gate insulating pattern GI may be interposed between the outer electrode PO2 and the external gate spacer OGS. For example, the gate insulating pattern GI may include at least one of silicon oxide (SiO₂), silicon oxynitride (SiON) or a high dielectric material. In the present specification, the high dielectric material is defined as a material having a higher dielectric constant than silicon oxide.

A first interlayered insulating layer ILD1 may be provided on the substrate 200. The first interlayered insulating layer ILD1 may cover side surfaces of the external gate spacers OGS and upper surfaces of the first and second source/drain patterns SD1 and SD2.

A second interlayered insulating layer ILD2 may cover the gate capping pattern GC on the first interlayered insulating layer ILD1. A third interlayered insulating layer ILD3 may be provided on the second interlayered insulating layer ILD2. For example, the first to third interlayered insulating layers ILD1, ILD2 and ILD3 may include silicon oxide (SiO₂).

Each of the active contacts CA may penetrate the first and second interlayered insulating layers ILD1 and ILD2. A lower portion of each of the active contacts CA may be buried in an upper portion of a corresponding source/drain pattern of the first source/drain pattern SD1 and the second source/drain pattern SD2. For example, each of the active contacts CA may include at least one of a metal material (for example, Ti, Mo, W, Cu, Al, Ta, Ru, Ir, Co, or the like), metal nitride (for example, nitride of Ti, Mo, W, Cu, Al, Ta, Ru, Ir, Co, or the like) or metal silicide (for example, silicide of Ti, Mo, W, Cu, Al, Ta, Ru, Ir, or the like).

A gate contact GT may penetrate the second interlayered insulating layer ILD2 and the gate capping pattern GC along the third direction D3. Each of the gate contacts GT may be buried in an upper portion of the outer electrode PO2 of the gate electrode GE. For example, each of the gate contacts GT may include at least one of a metal material (for example, Ti, Mo, W, Cu, Al, Ta, Ru, Ir, Co, or the like), or metal nitride (for example, nitride of Ti, Mo, W, Cu, Al, Ta, Ru, Ir, Co, or the like). Although not shown in the drawing, the gate contact GT may be provided in plurality, and each of the gate contacts GT may be connected to a corresponding gate electrode GE among the gate electrodes GE.

An upper insulating layer UIP including an insulating material may be provided on the active contact CA. The upper insulating layer UIP may be provided on the active contact CA adjacent to the gate contact GT among the active contacts CA.

A separation pattern DB may be provided on a side surface of each of the first active region AR1 and the second active region AR2. The separation pattern DB may be provided in plurality. The separation patterns DB may each extend along the second direction D2, and may be spaced apart from each other in the first direction D1. The first active region AR1 may be provided between the separation patterns DB adjacent to each other in the first direction D1. The second active region AR2 may be provided between the separation patterns DB adjacent to each other in the first direction D1. The separation pattern DB may include an insulating material. The single height cell SHC may be electrically separated from other logic cells adjacent to each other in the first direction D1.

Metal patterns MT may be provided in the third interlayered insulating layer ILD3. Via patterns VI may be interposed between the metal patterns MT and the active contacts CA, and between the metal patterns MT and the gate contacts GT. For example, although not shown in the drawing, a fourth interlayered insulating layer (not shown) including an insulating material may be provided on the third interlayered insulating layer ILD3. For example, although not shown in the drawing, each of the metal patterns MT and the via patterns VI may be provided in the fourth interlayered insulating layer as a plurality of layers, and each of the metal patterns MT and each of the via patterns VI may be alternately stacked. The metal patterns MT and the via patterns VI may include a metal material (for example, Ti, Mo, W, Cu, Al, Ta, Ru, Ir, Co, or the like).

A backside power rail MPR may extend in the substrate 200 along the first direction D1. The backside power rail MPR may be provided under the first active pattern AP1. The backside power rail MPR may be provided under the second active pattern AP2. The backside power rail MPR may extend under the first source/drain pattern SD1 along the first direction D1. The backside power rail MPR may extend under the second source/drain pattern SD2 along the first direction D1.

The backside conductive structure BCS may be interposed between the backside power rail MPR and the first pattern T1 of each of the first source/drain pattern SD1 and the second source/drain pattern SD2. The backside power rail MPR and the first pattern T1 of each of the first source/drain pattern SD1 and the second source/drain pattern SD2 may be connected to each other through the backside conductive structure BCS. The backside conductive structure BCS may include a backside power via MPV on the backside power rail MPR and a backside conductive contact BCA between the backside power via MPV and the first pattern T1 of each of the first source/drain pattern SD1 and the second source/drain pattern SD2.

For example, each of the backside power rail MPR and the backside conductive structure BCS may include a metal material (for example, Ti, Mo, W, Cu, Al, Ta, Ru, Ir, Co, or the like).

A power transfer network layer PDN may be provided on a lower surface of the substrate 200. The power transfer network layer PDN may include a plurality of lower wires (not shown) connected to the first source/drain pattern SD1 and the second source/drain pattern SD2 through the backside power rail MPR and the backside conductive structure BCS. For example, the power transfer network layer PDN may include a wire network for applying a source voltage. For example, the power transfer network layer PDN may include a wire network for applying a drain voltage.

A conductive pad CP may be provided in the single height cell SHC. The conductive pad CP may be provided on the first active region AR1 of the single height cell SHC. The first active region AR1 may include a measurement region MR and an adjacent region NR adjacent to the measurement region MR in the first direction D1, and the conductive pad CP may be provided on the adjacent region NR. In the present specification, the measurement region MR may be a region including a transistor (hereinafter, a measurement transistor) to be measured during analysis of electrical characteristics of the semiconductor device to be described later. In the present specification, one transistor may include a pair of source/drain patterns adjacent to each other in the first direction D1, a channel pattern therebetween, and a gate electrode crossing the channel pattern. A pair of the first source/drain patterns SD1 adjacent to each other on the measurement region MR in the first direction D1, the first channel pattern CH1 therebetween and the gate electrode GE crossing the first channel pattern CH1 may constitute the measurement transistor.

As illustrated in the drawing, the conductive pad CP may be shifted from the measurement region MR (in other words, the measurement transistor) in the first direction D1, but an embodiment of the disclosure is not limited thereto. Unlike what is illustrated in the drawing, a position of the measurement region MR may be changed depending on a position of the measurement transistor, and thus a position of the conductive pad CP may be also changed.

The conductive pad CP may penetrate each of the first to third interlayered insulating layers ILD1, ILD2 and ILD3, the first active pattern AP1 and the substrate 200 in the third direction D3. The conductive pad CP may penetrate the above components to extend to the backside power rail MPR, and may be connected to the backside power rail MPR. In the present specification, a meaning of the wording, “A is connected to B” may include not only “A and B are connected to each other by being in direct contact with each other”, but also “A and B are indirectly connected to each other through C (for example, a component having a conductivity) between A and B”. Here, component C may be a single component or a plurality of components. The conductive pad CP may vertically overlap the backside power rail MPR. For example, the conductive pad CP may penetrate the backside power rail MPR. For example, the conductive pad CP may be in contact with the backside power rail MPR.

For example, the conductive pad CP may include a metal material (for example, Ti, Mo, W, Cu, Al, Ta, Ru, Ir, Co, or the like).

It is illustrated in FIG. 2 that an upper surface of the conductive pad CP is coplanar with an upper surface of the third interlayered insulating layer ILD3, but an embodiment of the disclosure is not limited thereto. For another example, the upper surface of the conductive pad CP may be located inside the fourth interlayered insulating layer, or may be coplanar with an upper surface of the fourth interlayered insulating layer. For another example, the upper surface of the conductive pad CP may be located inside the third interlayered insulating layer ILD3. Referring to FIG. 3, unlike FIG. 2, the upper surface of the conductive pad CP may be coplanar with an upper surface of the active contact CA. Referring to FIG. 3, unlike FIG. 2, the upper surface of the conductive pad CP may be coplanar with each of an upper surface of the gate contact GT and an upper surface of the second interlayered insulating layer ILD2.

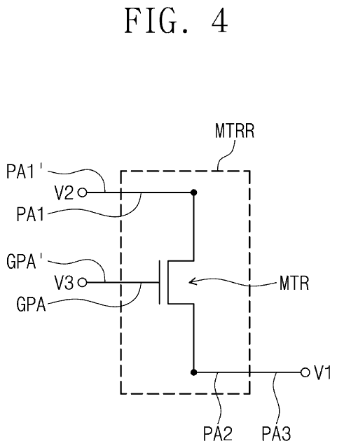

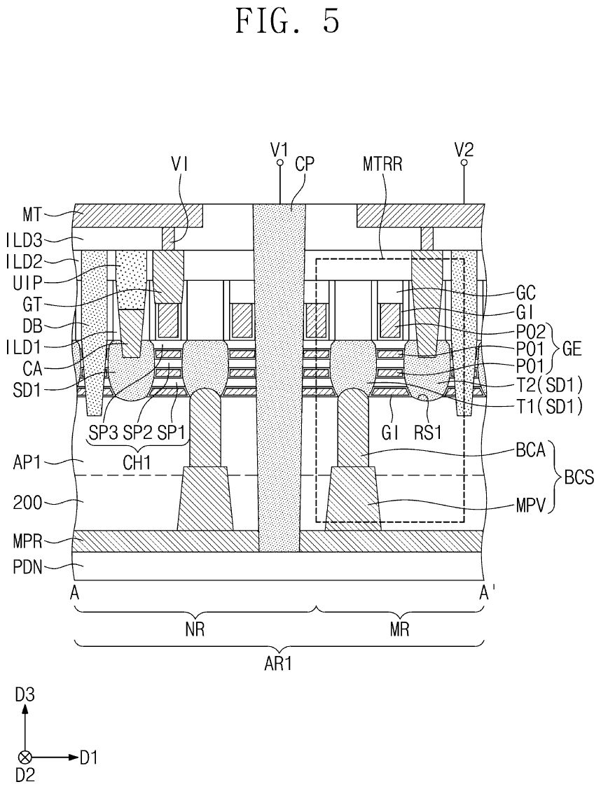

FIG. 4 is a block diagram illustrating a semiconductor device including a circuit of a measurement transistor and peripheral components connected to the measurement transistor, according to some embodiments of the disclosure. FIG. 5 is a cross-sectional view corresponding to line A-A′ of FIG. 1.

Referring to FIGS. 1, 4 and 5, a method for analyzing electrical characteristics of a measurement transistor MTR using the conductive pad CP will be described. The single height cell SHC may include the measurement transistor MTR in a measurement transistor region MTRR. The measurement transistor region MTRR may be provided on the measurement region MR, and may be a transistor region including the measurement transistor MTR, to measure the electrical characteristics thereof, among several transistors of the single height cell SHC.

The measurement transistor region MTRR may include a circuit of the measurement transistor MTR. The circuit of the measurement transistor MTR may include a first connection line PA1, a gate connection line GPA, and a second connection line PA2. The first connection line PA1 may correspond to the second pattern T2 of the first source/drain pattern SD1 and the active contact CA on the measurement region MR. The gate connection line GPA may correspond to the gate contact GT. The second connection line PA2 may correspond to the backside conductive structure BCS and the first pattern T1 of the first source/drain pattern SD1.

For example, the first connection line PA1 may be connected to a first external connection line PA1′. The first external connection line PA1′ may correspond to the metal pattern MT and the via pattern VI connected to the active contact CA on the measurement region MR. It is illustrated in the drawing that the first external connection line PA1′ is one metal pattern MT and one via pattern VI (hereinafter, a first metal layer) in the third interlayered insulating layer ILD3, but an embodiment of the disclosure is not limited thereto. A plurality of second to n-th metal layers provided on the first metal layer may be further provided. The second to n-th metal layers may include metal patterns MT and via patterns VI like the first metal layer. In this case, the first external connection line PA1′ may correspond to the metal patterns MT and the via patterns VI of the first to n-th metal layers connected to the active contact CA on the measurement region MR.

For example, the gate connection line GPA may be connected to an external gate connection line GPA′. The external gate connection line GPA′ may correspond to the metal patterns MT and the via patterns VI of the first to n-th metal layers connected to the gate contact GT on the measurement region MR.

For example, the second connection line PA2 may be connected to a third connection line PA3. The third connection line PA3 may correspond to the backside power rail MPR and the conductive pad CP.

For example, in order to analyze the electrical characteristics of the measurement transistor MTR, a first voltage V1 may be applied to the third connection line PA3, a second voltage V2 may be applied to the first external connection line PA1′, and a third voltage V3 may be applied to the external gate connection line GPA′.

For example, applying the first voltage V1 to the third connection line PA3 may include applying the first voltage V1 by making a separate probe in contact with the upper surface of the conductive pad CP. For example, the first voltage V1 may be a ground voltage.

For example, applying the second voltage V2 to the first external connection line PA1′ may include applying the second voltage V2 by making a separate probe in contact with the metal pattern MT or the via pattern VI of any one metal layer of the first to n-th metal layers connected to the first connection line PA1. For example, a value of the second voltage V2 may be variously changed depending on a measurement condition.

For example, applying the third voltage V3 to the external gate connection line GPA′ may include applying the third voltage V3 by making a separate probe in contact with the metal pattern MT or the via pattern VI of any one metal layer of the first to n-th metal layers connected to the gate connection line GPA. Accordingly, the third voltage V3 may be transferred to the gate electrode GE. For example, the third voltage V3 may correspond to a voltage for turning the measurement transistor on.

Since the first to third voltages V1, V2 and V3 are applied under the above condition, the electrical characteristics of the measurement transistor MTR may be analyzed. For example, since the first to third voltages V1, V2 and V3 are applied under the above condition, an applied current may sequentially flow in the first external connection line PA1′, the first connection line PA1, the first channel pattern CH1, the second connection line PA2 and the third connection line PA3. The electrical characteristics of the measurement transistor MTR may be analyzed by detecting the current passing through the above paths using a separate detector.

For example, using the above analysis method, the electrical characteristics may be analyzed, and additionally whether or not the metal patterns MT and the via patterns VI of a back end of line (BEOL) connected to the measurement transistor MTR are connected and whether or not the backside conductive structure BCS and the backside power rail MPR connected to the measurement transistor MTR are connected may be confirmed by measuring an electron beam absorbed current (EBAC).

For another example, although not shown in the drawing, the conductive pad CP may be formed so as to penetrate the backside power rail MPR to be connected to the power transfer network layer PDN. In this case, the conductive pad CP may be connected to separate conductive lines provided inside the power transfer network layer PDN. Accordingly, whether or not conductive lines inside the power transfer network layer PDN connected to the measurement transistor MTR are connected may be also confirmed using the analysis method described above.

In addition, a three-terminal measurement method is illustrated in the drawing in order to measure the electrical characteristics of the measurement transistor MTR and to confirm whether or not peripheral components are connected, but an embodiment of the disclosure is not limited thereto. For example, the third voltage V3 may not be applied, and thus the gate electrode GE may be floated. Even in this case, the measurement transistor may be indirectly turned on by a relative electric potential difference between the first voltage V1 and the second voltage V2. Accordingly, a current applied in a two-terminal measurement method may sequentially flow in the first external connection line PA1′, the first connection line PA1, the first channel pattern CH1, the second connection line PA2 and the third connection line PA3. The electrical characteristics of the measurement transistor MTR may be analyzed by detecting the current passing through the above paths using a separate detector.

According to the disclosure, the conductive pad CP may be connected to the backside power rail MPR connected to the measurement transistor MTR in order to analyze the electrical characteristics of the measurement transistor MTR and whether or not the peripheral components are connected. Since the first voltage V1 (for example, a ground voltage) is applied to the conductive pad CP, a current applied from the BEOL by the second voltage V2 may be stably transferred to the measurement transistor MTR, the backside conductive structure BCS, the backside power rail MPR and the conductive pad CP.

For example, when the conductive pad CP is not provided, the backside power rail MPR may be buried in the substrate 200 and thus a source terminal cannot be in contact with the backside power rail MPR. In this case, a I-V data of the measurement transistor MTR connected to the backside power rail MPR cannot be measured. In addition, the current applied by the BEOL does not pass through the stable path described above, and passes through the measurement transistor MTR to flow in various regions in which measuring is unnecessary. Accordingly, a noise of an analysis data may increase, and analysis reliability may be reduced.

However, according to the disclosure, the above limitation may be solved by providing the conductive pad CP connected to the backside power rail MPR, and applying the first voltage V1 (for example, the ground voltage) to the conductive pad CP. As a result, according to the disclosure, the electrical characteristics of the measurement transistor MTR may be analyzed in a structure in which power is supplied to the measurement transistor MTR through the backside conductive structure BCS. In addition, according to the disclosure, the noise of an analysis data may be reduced in the above method. Accordingly, the analysis reliability of the semiconductor device may be improved.

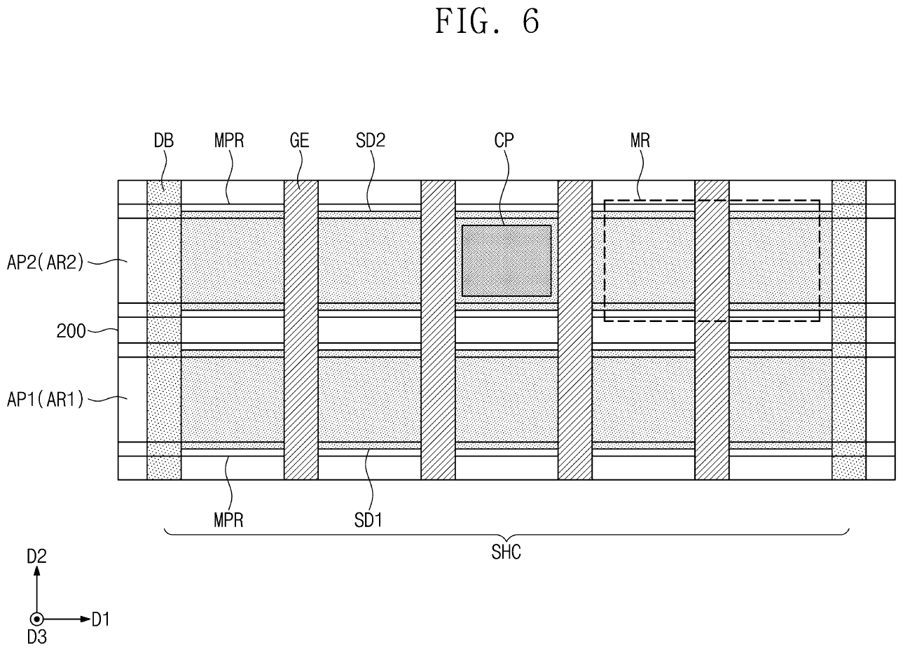

FIGS. 6, 7 and 8 are plan views illustrating a semiconductor device according to some embodiments of the disclosure, respectively.

Referring to FIGS. 6 to 8, a position of the conductive pad CP may be variously changed by a person of ordinary skill in the art. For example, the position of the conductive pad CP may be variously changed by changing a position of the measurement region MR.

Referring to FIG. 6, unlike what is described with reference to FIG. 1, the second active region AR2, not the first active region AR1, may include the measurement region MR. The conductive pad CP may be connected to the backside power rail MPR provided under the second source/drain pattern SD2 of the second active region AR2. Accordingly, as described with reference to FIGS. 4 and 5, the electrical characteristics of the measurement transistor on the measurement region MR of the second active region AR2 may be analyzed by using the conductive pad CP.

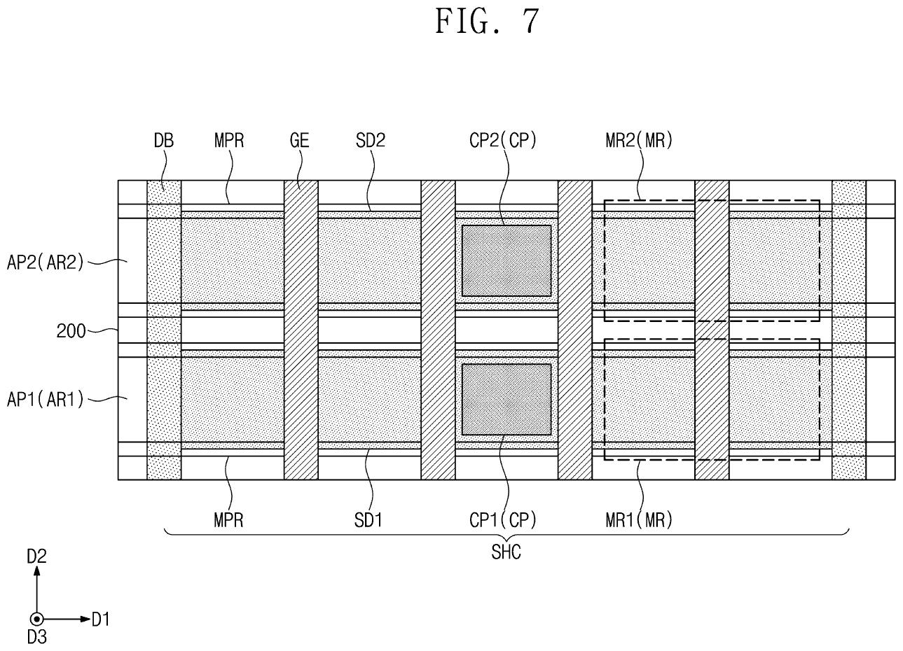

Referring to FIG. 7, unlike what is described with reference to FIG. 1, the measurement region MR may be provided in plurality. For example, two measurement regions MR are illustrated, but an embodiment of the disclosure is not limited thereto. The measurement region MR may include a first measurement region MR1 and a second measurement region MR2. The first active region AR1 may include the first measurement region MR1, and the second active region AR2 may include the second measurement region MR2.

The conductive pad CP may be provided in plurality. For example, two conductive pads CP are illustrated, but an embodiment of the disclosure is not limited thereto. The conductive pad CP may include a first conductive pad CP1 on the first active region AR1 and a second conductive pad CP2 on the second active region AR2.

A relationship between the first conductive pad CP1 and the first measurement region MR1 may be the same as or similar to what is described with reference to FIGS. 1 to 5. A relationship between the second conductive pad CP2 and the second measurement region MR2 may be the same as or similar to what is described with reference to FIG. 6.

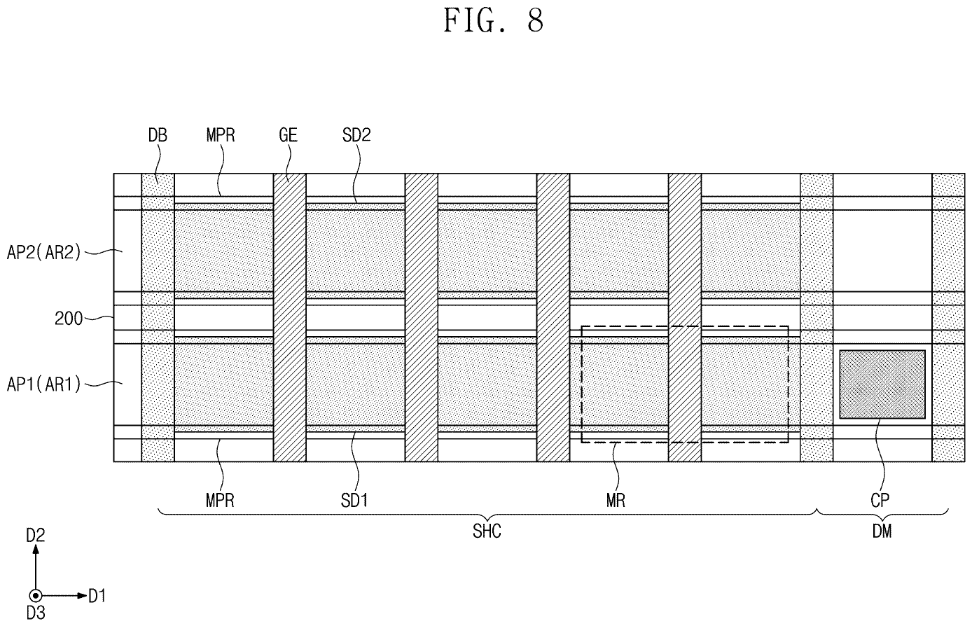

Referring to FIG. 8, unlike what is described with reference to FIG. 1, the conductive pad CP may be provided on a dummy region DM. The dummy region DM may be adjacent to the single height cell SHC in the first direction D1. For example, on a plan view, the dummy region DM may be interposed between the separation patterns DB, but an embodiment of the disclosure is not limited thereto.

The backside power rail MPR may extend from the single height cell SHC to the dummy region DM along the first direction D1. The conductive pad CP on the dummy region DM may penetrate the peripheral components along the third direction D3, and may be connected to the backside power rail MPR. Accordingly, as described with reference to FIGS. 4 and 5, the electrical characteristics of the measurement transistor on the measurement region MR of the first active region AR1 may be analyzed by using the conductive pad CP. Although not shown in the drawing, when the second active region AR2 includes the measurement region MR, the conductive pad CP on the dummy region DM may vertically overlap the backside power rail MPR on the second active region AR2, and may be connected to the backside power rail MPR.

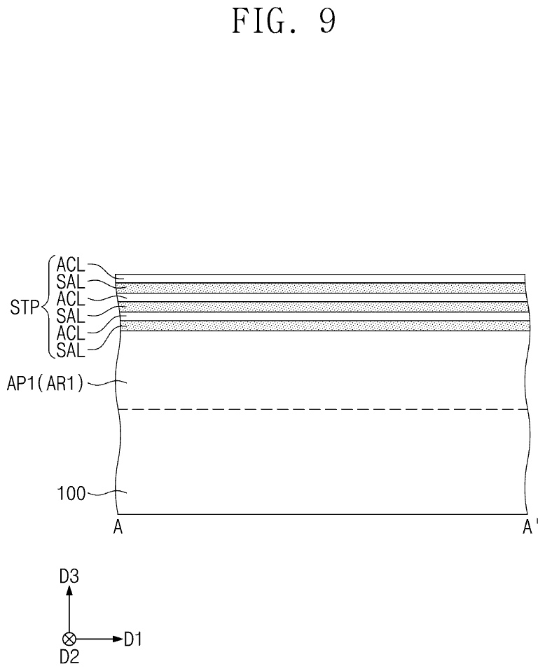

FIGS. 9 to 14 are diagrams for explaining a method for manufacturing a semiconductor device according to some embodiments of the disclosure. Specifically, each of FIGS. 9 to 14 is a cross-sectional view corresponding to line A-A′ of FIG. 1.

Referring to FIGS. 1 and 9, a semiconductor substrate 100 including the first active region AR1 and the second active region AR2 may be provided. For example, the semiconductor substrate 100 may be a semiconductor substrate, including a semiconductor material, such as a silicon single-crystalline substrate, a silicon-germanium substrate, or an SOI substrate. Stack patterns STP may be formed on the first active region AR1 and the second active region AR2. For example, forming the stack patterns STP may include alternately stacking semiconductor layers ACL and sacrificial layers SAL on the semiconductor substrate 100, forming mask patterns (not shown) extending in the first direction D1, and performing a patterning process by using the mask patterns as etching masks. During the patterning process, the semiconductor substrate 100 may be partially removed together, and the trenches TR defining the first active pattern AP1 and the second active pattern AP2 may be formed. Element separation patterns (not shown) may be formed so as to fill the trenches TR.

The sacrificial layers SAL may include a material having etching selectivity with respect to the semiconductor layers ACL. Accordingly, during performing a process of removing the sacrificial layers SAL, to be described later, although the sacrificial layers SAL are removed, the semiconductor layers ACL may not be removed or may be less removed. For example, the semiconductor layers ACL may include one among silicon (Si), germanium (Ge) and silicon-germanium (SiGe), and the sacrificial layers SAL may include one, among silicon (Si), germanium (Ge) and silicon-germanium (SiGe), different from the semiconductor layers ACL.

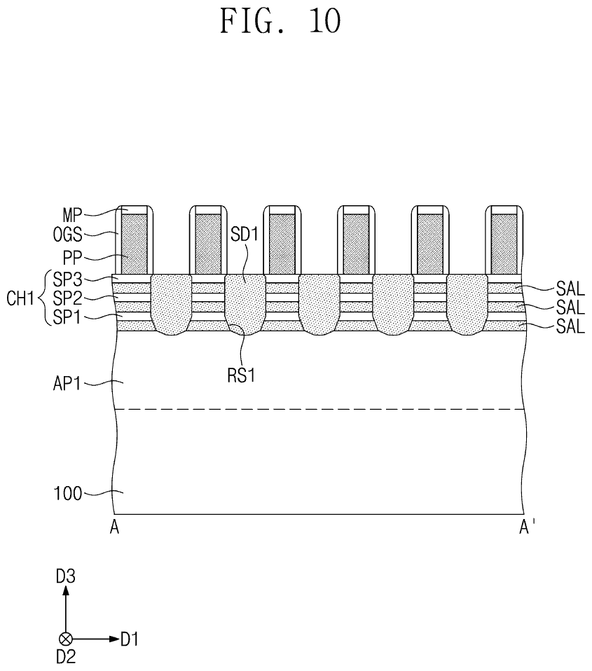

Referring to FIGS. 1 and 10, sacrificial patterns PP may be formed so as to extend on the semiconductor substrate 100 along the second direction D2. The sacrificial patterns PP may be formed so as to cover upper surfaces of the element separation patterns, and side surfaces and upper surfaces of the stack patterns STP. For example, forming the sacrificial patterns PP may include forming a sacrificial layer (not shown) on a front surface of the semiconductor substrate 100, forming hard mask patterns MP on the sacrificial layer, and forming the sacrificial patterns PP by partially removing the sacrificial layer using the hard mask patterns MP as etching masks. For example, the sacrificial pattern PP may include polysilicon. Thereafter, the external gate spacers OGS may be formed on side surfaces of the sacrificial patterns PP.

The first recesses RS1 may be formed in the stack pattern STP on the first active pattern AP1. The second recesses (not shown) may be formed in the stack pattern STP on the second active pattern AP2. For example, the first recess RS1 and the second recess may be formed by partially removing the stack pattern STP using the hard mask patterns MP as etching masks.

The semiconductor layers ACL on the first active pattern AP1 may be separated into the first channel patterns CH1 spaced apart from each other in the first direction D1 by the first recesses RS1. The semiconductor layers ACL on the second active pattern AP2 may be separated into the second channel patterns (not shown) spaced apart from each other in the first direction D1 by the second recesses.

The first source/drain patterns SD1 may be formed in the first recesses RS1. For example, during a process of forming the first source/drain pattern SD1, an impurity (for example, phosphorous, arsenic or antimony) that makes the first source/drain pattern SD1 have an N-type may be in-situ injected into the first source/drain pattern SD1. For another example, after the first source/drain pattern SD1 is formed, the impurity may be injected into the first source/drain pattern SD1.

The second source/drain patterns SD2 may be formed in the second recesses. For example, during a process of forming the second source/drain pattern SD2, an impurity (for example, boron, gallium or indium) that makes the second source/drain pattern SD2 have a P-type may be in-situ injected into the second source/drain pattern SD2. For another example, after the second source/drain pattern SD2 is formed, the impurity may be injected into the second source/drain pattern SD2.

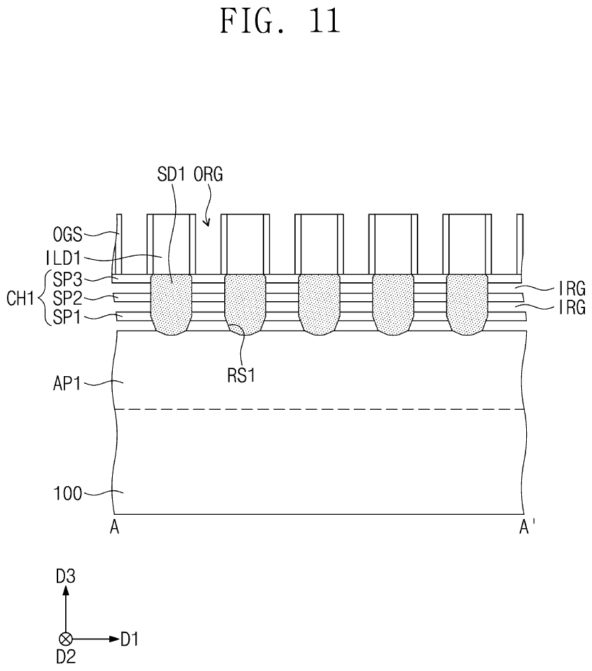

Referring to FIGS. 1 and 11, the first interlayered insulating layer ILD1 may be formed so as to cover the first source/drain pattern SD1, the second source/drain pattern SD2, the hard mask patterns MP (see FIG. 10) and the external gate spacers OGS. Thereafter, the first interlayered insulating layer ILD1 on upper surfaces of the sacrificial patterns PP (see FIG. 10) may be removed. During the removing process, the hard mask patterns MP (see FIG. 10) may be removed together, and the sacrificial patterns PP (see FIG. 10) may be exposed.

Thereafter, the exposed sacrificial patterns PP (see FIG. 10) may be removed, and an outer region ORG may be formed in regions in which the sacrificial patterns PP (see FIG. 11) are removed. The first channel pattern CH1, the second channel pattern and the sacrificial layers SAL may be exposed outside by the outer region ORG.

Thereafter, the exposed sacrificial layers SAL may be selectively removed. In this case, the first to third semiconductor patterns SP1, SP2, and SP3 may not be removed or may be less removed due to high etching selectivity of the sacrificial layers SAL. Inner regions IRG may be formed in regions in which the sacrificial layers SAL are removed.

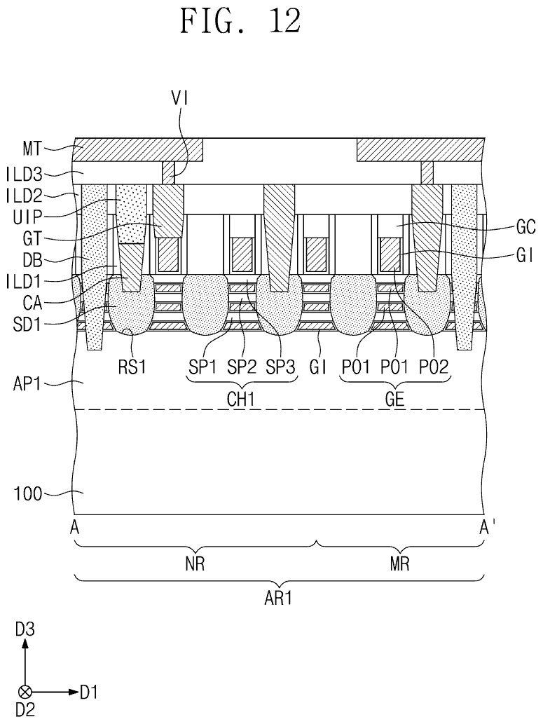

Referring to FIGS. 1 and 12, the gate insulating pattern GI may be formed in each of the inner regions IRG and the outer region ORG. The gate insulating pattern GI may be formed so as to surround each of the first to third semiconductor patterns SP1, SP2, and SP3.

The gate electrode GE may be formed on the gate insulating pattern GI. The gate electrode GE may include the inner electrode PO1 formed in each of the inner regions IRG and the outer electrode PO2 formed in the outer region ORG. Thereafter, the gate capping pattern GC may be formed on the outer electrode PO2 of the gate electrode GE.

The second interlayered insulating layer ILD2 may be formed on the first interlayered insulating layer ILD1 and the gate capping pattern GC. The active contacts CA may be formed so as to penetrate the first and second interlayered insulating layers ILD1 and ILD2. The gate contacts GT may be formed so as to penetrate the second interlayered insulating layer ILD2 and the gate capping pattern GC. Upper portions of some of the active contacts CA may be replaced with the upper insulating layer UIP.

The separation pattern DB may be formed so as to penetrate the first and second interlayered insulating layers ILD1 and ILD2. The third interlayered insulating layer ILD3 may be formed on the second interlayered insulating layer ILD2. The metal patterns MT and the vias VI may be formed in the third interlayered insulating layer ILD3. Although not shown in the drawing, the fourth interlayered insulating layer (not shown) may be formed on the third interlayered insulating layer ILD3, and the metal patterns MT and the vias VI may be formed in the fourth interlayered insulating layer.

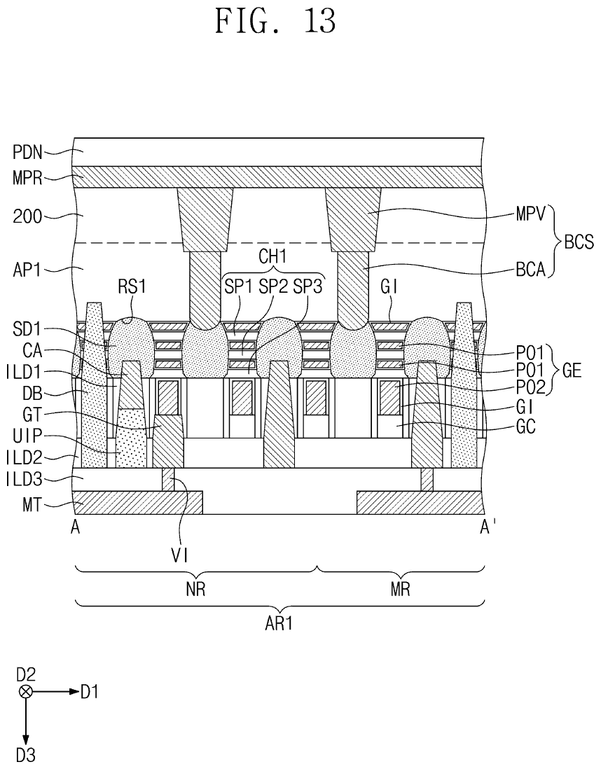

Referring to FIGS. 1 and 13, after a BEOL process is completed, the semiconductor substrate 100 described with reference to FIG. 9 may be turned over. Accordingly, a lower surface of the semiconductor substrate 100 (see FIG. 9) may be exposed. A thickness of the semiconductor substrate 100 (see FIG. 9) may be reduced by performing a planarization process on the exposed surface of the semiconductor substrate 100 (see FIG. 9). For example, the semiconductor substrate 100 (see FIG. 9) may be completely or partially removed in the planarization process.

Insulating layers (not shown) including an insulating material may be formed so as to fill a region in which the semiconductor substrate 100 (see FIG. 9) is removed. The insulating layers and a remaining portion of the semiconductor substrate 100 (see FIG. 9) may constitute the substrate 200.

Referring to FIG. 13, the substrate 200 may be partially removed by performing a patterning process on the substrate 200. The backside conductive structure BCS may be formed in a region in which the substrate 200 is partially removed. The backside power rail MPR may be formed on the backside conductive structure BCS. The power transfer network layer PDN may be formed on the lower surface of the substrate 200.

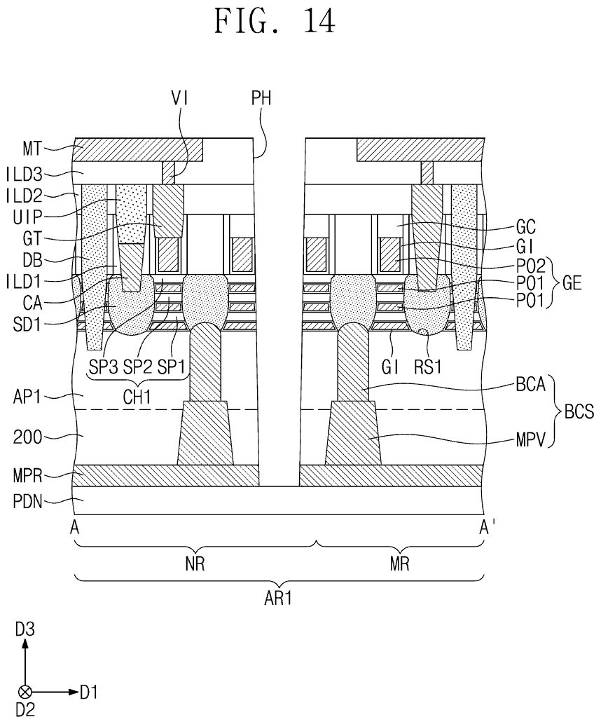

Referring to FIGS. 1 and 14, the substrate 200 may be turned over again. Thereafter, a pad hole PH may be formed by performing a process of removing portions of the first to third interlayered insulating layers ILD1, ILD2 and ILD3, a portion of the first active pattern AP1 and a portion of the substrate 200. The backside power rail MPR may be partially exposed in the removing process.

For example, the removing process may be performed in a dry etching process and a wet etching process. For another example, the removing process may be performed with a focused ion beam apparatus. The focused ion beam apparatus may include an ion beam device. The ion beam device may irradiate the semiconductor device according to the disclosure with an ion beam. Accordingly, the pad hole PH may be formed by performing the removing process.

Referring back to FIGS. 1 and 2, the conductive pad CP may be formed in the pad hole PH (see FIG. 14). For example, after the conductive pad CP is formed, the single height cell SHC may be utilized as a specimen for analyzing the electrical characteristics of the measurement transistor MTR (see FIG. 4) described with reference to FIGS. 4 and 5 by using the conductive pad CP.

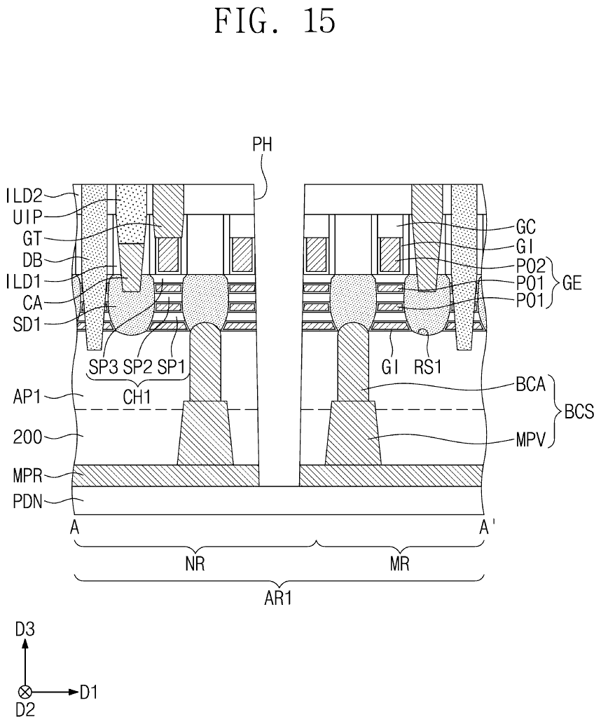

FIG. 15 is a diagram for explaining a method for manufacturing a semiconductor device according to some embodiments of the disclosure. Specifically, FIG. 15 is a cross-sectional view corresponding to line A-A′ of FIG. 1.

Referring to FIGS. 1 and 15, a process of removing each of the third interlayered insulating layer ILD3, the metal patterns MT and the via patterns VI may be performed before the process of forming the pad hole PH described with reference to FIG. 14. Accordingly, the upper surface of each of the active contact CA and the gate contact GT may be exposed.

Thereafter, the pad hole PH may be formed by performing a process of removing the portions of the first and second interlayered insulating layers ILD1 and ILD2, the portion of the first active pattern AP1 and the portion of the substrate 200.

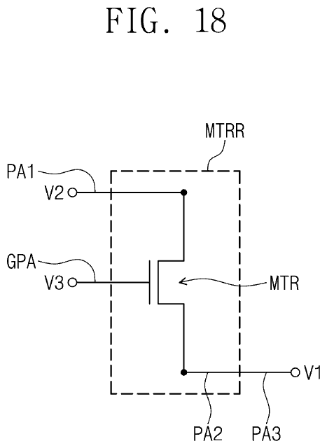

Referring back to FIGS. 1 and 3, the conductive pad CP may be formed in the pad hole PH (see FIG. 15). For example, after the conductive pad CP is formed, the single height cell SHC may be utilized as the specimen for analyzing the electrical characteristics of the measurement transistor MTR (see FIG. 18) to be described later by using the conductive pad CP. For example, after analyzing the electrical characteristics of the measurement transistor MTR (see FIG. 18) is completed, the third interlayered insulating layer ILD3 may be formed on the second interlayered insulating layer ILD2. The metal patterns MT and the vias VI may be formed in the third interlayered insulating layer ILD3.

For another example, the pad hole PH may be formed at a time different from the time described above. For example, after the process of forming the separation pattern DB described with reference to FIG. 12, the semiconductor substrate 100 (see FIG. 12) may be turned over. Thereafter, as described with reference to FIG. 13, the substrate 200, the backside conductive structure BCS, the backside power rail MPR and the power transfer network layer PDN may be formed.

Thereafter, referring to FIGS. 1 and 15, the substrate 200 may be turned over again. The pad hole PH may be formed by performing the process of removing the portions of the first and second interlayered insulating layers ILD1 and ILD2, the portion of the first active pattern AP1 and the portion of the substrate 200.

Referring back to FIGS. 1 and 3, the conductive pad CP may be formed in the pad hole PH (see FIG. 15). For example, after the conductive pad CP is formed, the single height cell SHC may be utilized as the specimen for analyzing the electrical characteristics of the measurement transistor MTR (see FIG. 18) to be described later by using the conductive pad CP. For example, after analyzing the electrical characteristics of the measurement transistor MTR (see FIG. 18) is completed, the third interlayered insulating layer ILD3 may be formed on the second interlayered insulating layer ILD2. The metal patterns MT and the vias VI may be formed in the third interlayered insulating layer ILD3.

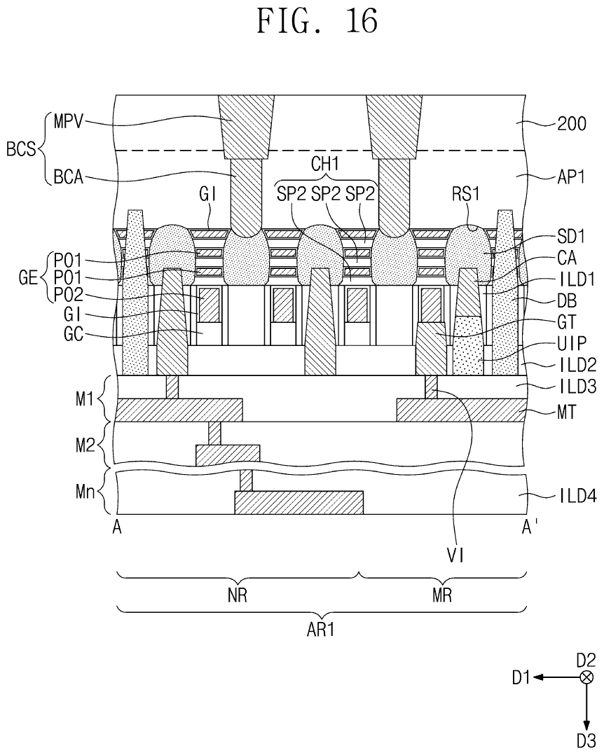

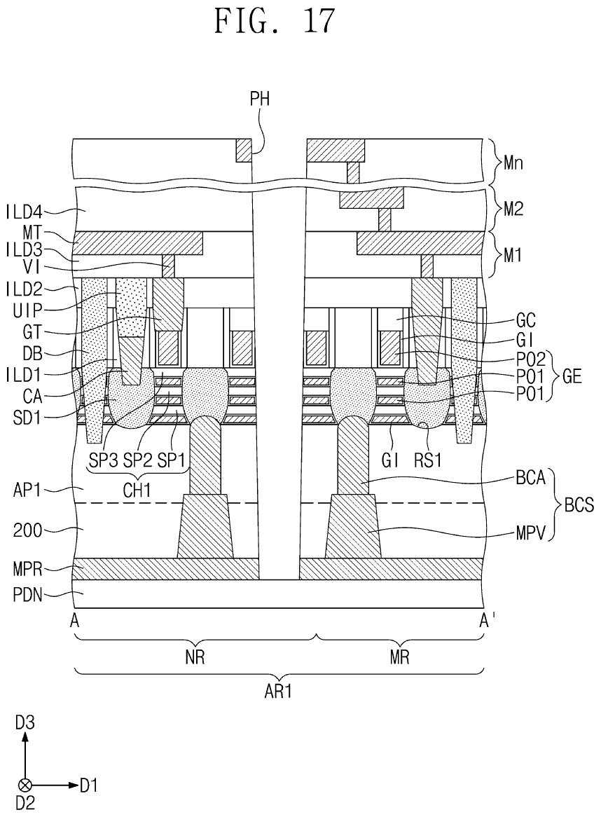

FIGS. 16 and 17 are diagrams for explaining a method for manufacturing a semiconductor device according to some embodiments of the disclosure. Specifically, FIGS. 16 and 17 are cross-sectional views corresponding to line A-A′ of FIG. 1, respectively.

Referring to FIGS. 1 and 16, after the process of forming the metal patterns MT and the vias VI described with reference to FIG. 12, the semiconductor substrate 100 (see FIG. 12) may be turned over. The metal patterns MT and the vias VI may constitute first to n-th metal layers M1, M2 to Mn in the third interlayered insulating layer ILD3 and a fourth interlayered insulating layer ILD4.

Thereafter, as described with reference to FIG. 13, the substrate 200 and the backside conductive structure BCS may be formed.

Referring to FIGS. 1 and 17, the substrate 200 may be turned over again. Thereafter, the pad hole PH may be formed by performing a process of removing a portion of each of the first to n-th metal layers M1, M2 to Mn, portions of the first interlayered insulating layer ILD1 and the second interlayered insulating layer ILD2, a portion of the first active pattern AP1 and a portion of the substrate 200.

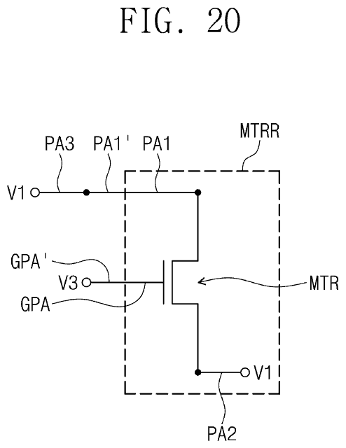

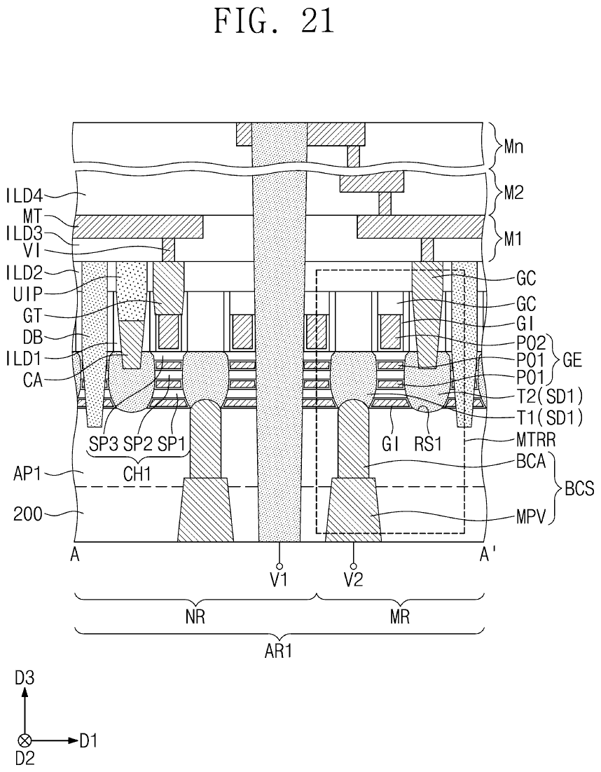

Thereafter, although not shown in the drawing, the conductive pad CP may be formed in the pad hole PH. Thereafter, a planarization process may be performed so as to expose a lower surface of the backside conductive structure BCS. Accordingly, the semiconductor device of FIG. 21 to be described later may be manufactured. For example, after the planarization process is performed, the single height cell SHC may be utilized as the specimen for analyzing the electrical characteristics of the measurement transistor MTR (see FIG. 20) to be described later by using the conductive pad CP.

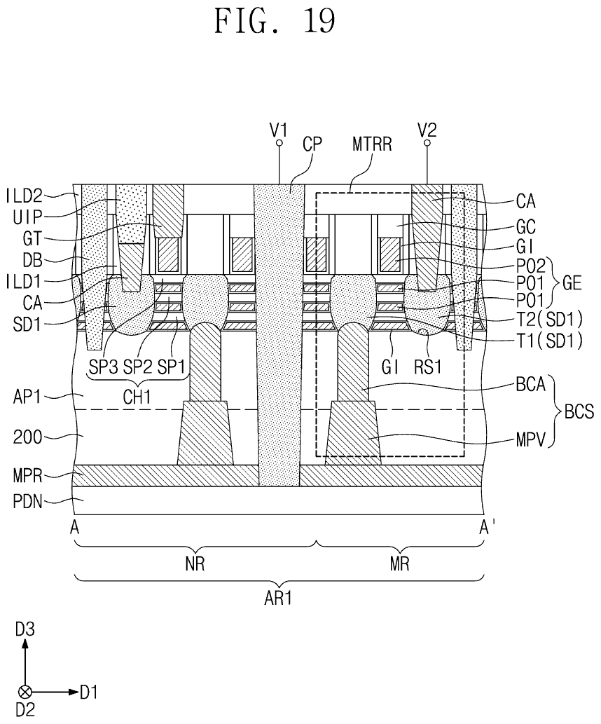

FIG. 18 is a block diagram illustrating a semiconductor device including a circuit of the measurement transistor and the peripheral components connected to the measurement transistor, according to some embodiments of the disclosure. FIG. 19 is a cross-sectional view corresponding to line A-A′ of FIG. 1.

Referring to FIGS. 1, 18 and 19, the semiconductor device according to some embodiments of the disclosure of FIG. 19 may be a semiconductor device manufactured in the manufacturing method described with reference to FIG. 15. For example, after entire manufacturing processes of the semiconductor device are partially processed, the electrical characteristics of the measurement transistor MTR of the semiconductor device and whether or not the peripheral components are connected may be measured.

Unlike what is described with reference to FIG. 4, each of the active contact CA and the gate contact GT may be exposed. Accordingly, without the first external connection line PA1′ and the external gate connection line GPA′ described with reference to FIG. 4, the second voltage V2 may be applied to the first connection line PA1, and the third voltage V3 may be applied to the gate connection line GPA.

For example, applying the second voltage V2 to the first connection line PA1 may include applying the second voltage V2 by making a separate probe in contact with an upper surface of the active contact CA. For example, applying the third voltage V3 to the gate connection line GPA may include applying the third voltage V3 by making a separate probe in contact with an upper surface of the gate contact GT.

The electrical characteristics of the measurement transistor MTR and whether or not the peripheral components are connected may be analyzed by applying the first to third voltages V1, V2 and V3 under the above condition. The above analysis method may be the same as or similar to what is described with reference to FIGS. 4 and 5.

For another example, the electrical characteristics of the measurement transistor MTR and whether or not the peripheral components are connected may be analyzed in the two-terminal method, not the three-terminal method described above. The above analysis method may be the same as or similar to what is described with reference to FIGS. 4 and 5.

The electrical characteristics of the measurement transistor MTR of the semiconductor device and whether or not the peripheral components are connected may be analyzed during processes of manufacturing the semiconductor device in the above analysis method. Accordingly, the analysis reliability of the semiconductor device may be improved.

FIG. 20 is a block diagram illustrating a semiconductor device including a circuit of the measurement transistor and the peripheral components connected to the measurement transistor, according to some embodiments of the disclosure. FIG. 21 is a cross-sectional view corresponding to line A-A′ of FIG. 1.

Referring to FIGS. 1, 20 and 21, the semiconductor device according to some embodiments of the disclosure of FIG. 21 may be a semiconductor device manufactured in the manufacturing method described with reference to FIGS. 16 and 17. For example, after the entire manufacturing processes of the semiconductor device are partially processed, the electrical characteristics of the measurement transistor MTR of the semiconductor device and whether or not the peripheral components are connected may be measured.

Unlike what is described with reference to FIG. 4, the third connection line PA3 may not be directly connected to the second connection line PA2, and may be directly connected to the first external connection line PA1′. In other words, the conductive pad CP may not be directly connected to the backside conductive structure BCS on the measurement region MR, and may be directly connected to the metal pattern MT of the n-th metal layer Mn.

Unlike what is described with reference to FIG. 4, a lower surface of the conductive pad CP and the lower surface of the backside conductive structure BCS on the measurement region MR may be exposed. For example, applying the first voltage V1 to the third connection line PA3 may include applying the first voltage V1 by making a separate probe in contact with the lower surface of the conductive pad CP. For example, unlike what is described with reference to FIG. 4, the second voltage V2 may be applied to the second connection line PA2. For example, applying the second voltage V2 to the second connection line PA2 may include applying the second voltage V2 by making a separate probe in contact with the lower surface of the backside conductive structure BCS on the measurement region MR.

The electrical characteristics of the measurement transistor MTR and whether or not the peripheral components are connected (for example, whether or not the first to n-th metal layers M1, M2 to Mn are connected) may be analyzed by applying the first to third voltages V1, V2 and V3 under the above condition. The above analysis method may be the same as or similar to what is described with reference to FIGS. 4 and 5.

For another example, the electrical characteristics of the measurement transistor MTR and whether or not the peripheral components are connected may be analyzed in the two-terminal method, not the three-terminal method described above. The above analysis method may be the same as or similar to what is described with reference to FIGS. 4 and 5.

The electrical characteristics of the measurement transistor MTR of the semiconductor device and whether or not the peripheral components are connected may be analyzed during the processes of manufacturing the semiconductor device in the above analysis method. Accordingly, the analysis reliability of the semiconductor device may be improved.

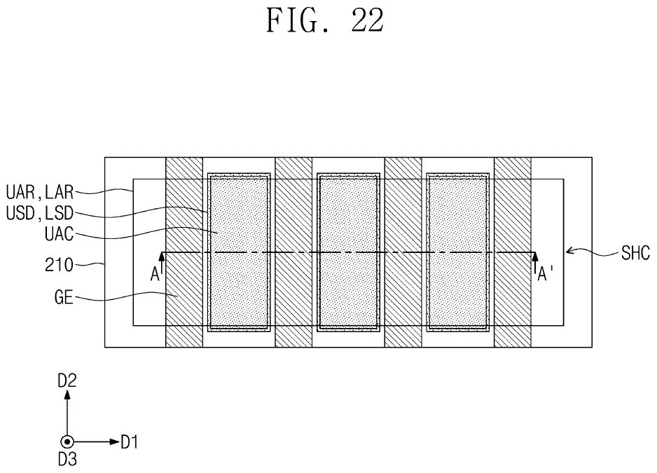

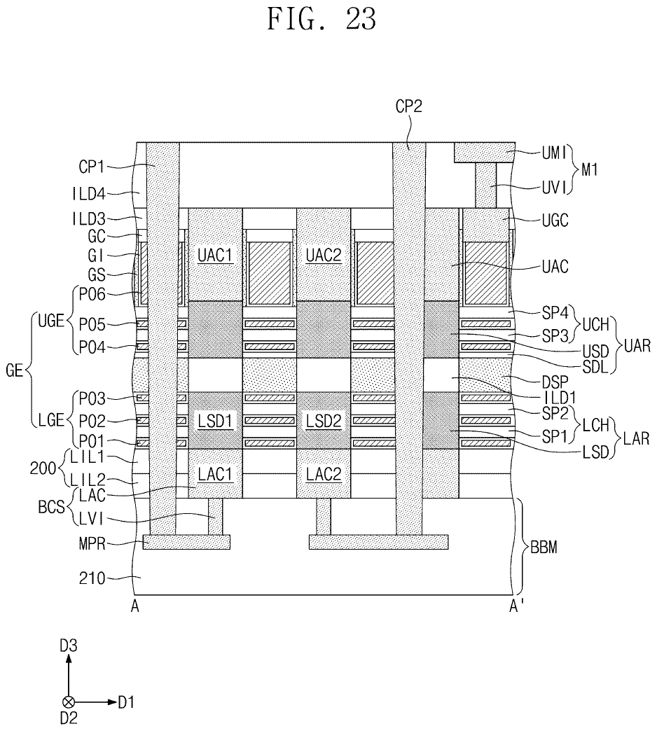

FIG. 22 is a plan view illustrating a semiconductor device according to some embodiments of the disclosure. FIG. 23 is cross-sectional views corresponding to line A-A′ of FIG. 22.

Referring to FIGS. 22 and 23, for example, the substrate 200 may include a first lower insulating layer LIL1 and a second lower insulating layer LIL2. The first lower insulating layer LIL1 may be provided on the second lower insulating layer LIL2.

A lower active region LAR and an upper active region UAR sequentially stacked on the substrate 200 may be provided. Any one of the lower and upper active regions LAR and UAR may be a PMOSFET region, and the other one of the lower and upper active regions LAR and UAR may be an NMOSFET region. The lower active region LAR may be provided in a bottom tier of a front-end-of-line (FEOL) layer, and the upper active region UAR may be provided in a top tier of the FEOL layer. The NMOSFET and the PMOSFET of the lower and upper active regions LAR and UAR may be vertically stacked to constitute a three-dimensional stack transistor. For example, the lower active region LAR may be the PMOSFET region, and the upper active region UAR may be the NMOSFET region.

The lower active region LAR may include lower source/drain patterns LSD and lower channel patterns LCH including the first semiconductor pattern SP1 and the second semiconductor pattern SP2. For example, the lower source/drain patterns LSD may be doped with an impurity to have a P-type. The lower source/drain patterns LSD may include silicon (Si) and/or silicon-germanium (SiGe).

The first interlayered insulating layer ILD1 may be provided on the lower source/drain pattern LSD. The first interlayered insulating layer ILD1 may cover the lower source/drain patterns LSD. A lower active contact LAC may be provided under the lower source/drain pattern LSD.

The upper active region UAR may be provided on the first interlayered insulating layer ILD1. The upper active region UAR may include upper source/drain patterns USD and upper channel patterns UCH including the third semiconductor pattern SP3 and a fourth semiconductor pattern SP4. The upper channel patterns UCH may respectively vertically overlap the lower channel patterns LCH. The upper source/drain patterns USD may respectively vertically overlap the lower source/drain patterns LSD. The upper source/drain patterns USD may be doped with an impurity to have an N-type. The upper source/drain patterns USD may include silicon (Si) and/or silicon-germanium (SiGe).

At least one dummy channel pattern DSP may be interposed between the lower channel pattern LCH and the upper channel pattern UCH thereon. A seed layer SDL may be interposed between the dummy channel pattern DSP and the upper channel pattern UCH.

The gate electrode GE may be provided on the stacked lower and upper channel patterns LCH and UCH. The gate electrode GE may include a lower gate electrode LGE provided in the bottom tier of the FEOL layer, that is, in the lower active region LAR, and an upper gate electrode UGE provided in the top tier of the FEOL layer, that is, in the upper active region UAR.

The lower gate electrode LGE may include a first inner electrode PO1 interposed between the first lower insulating layer LIL1 and the first semiconductor pattern SP1, a second inner electrode PO2 interposed between the first semiconductor pattern SP1 and the second semiconductor pattern SP2, and a third inner electrode PO3 interposed between the second semiconductor pattern SP2 and the dummy channel pattern DSP.

The upper gate electrode UGE may include a fourth inner electrode PO4 interposed between the dummy channel pattern DSP (or the seed layer SDL) and the third semiconductor pattern SP3, a fifth inner electrode PO5 interposed between the third semiconductor pattern SP3 and the fourth semiconductor pattern SP4, and an outer electrode PO6 on the fourth semiconductor pattern SP4.

A pair of gate spacers GS may be respectively disposed on both sidewalls of the gate electrode GE (or the outer electrode PO6). The gate capping pattern GC may be provided on an upper surface of the gate electrode GE. The gate insulating pattern GI may be interposed between the gate electrode GE and the first to fourth semiconductor patterns SP1 to SP4. The second interlayered insulating layer (not shown) and the third interlayered insulating layer ILD3 may be sequentially provided on the lower source/drain pattern LSD and the first interlayered insulating layer ILD1.

Upper active contacts UAC penetrating the third interlayered insulating layer ILD3 to be respectively electrically connected to the upper source/drain patterns USD may be provided. An upper gate contact UGC penetrating the third interlayered insulating layer ILD3 and the gate capping pattern GC to be electrically connected to the upper gate electrode UGE may be provided.

The fourth interlayered insulating layer ILD4 may be provided on the third interlayered insulating layer ILD3. The first metal layer M1 may be provided in the fourth interlayered insulating layer ILD4. The first metal layer M1 may include upper wires UMI and upper vias UVI.

Additional metal layers (for example, M2, M3, M4 and the like) may be stacked on the first metal layer M1. The first metal layer M1 and the metal layers (for example, M2, M3, M4 and the like) on the first metal layer M1 may constitute a back end of line (BEOL) layer of the semiconductor device.

A lower interlayered insulating layer 210 may be provided under the lower surface of the substrate 200. A backside metal layer BSM may be provided in the lower interlayered insulating layer 210. The backside metal layer BSM may include lower vias LVI and the backside power rail MPR. Additional lower metal layers may be stacked under the backside metal layer BSM. Some of the lower metal layers may be connected to the backside power rail MPR. According to an embodiment of the disclosure, the lower metal layers may include a power transfer network. The lower vias LVI and the lower active contact LAC may constitute the backside conductive structure BCS.

Each of the first conductive pad CP1 and the second conductive pad CP2 may penetrate the substrate 200, the third interlayered insulating layer ILD3 and the fourth interlayered insulating layer ILD4, and may be connected to the backside power rail MPR. Accordingly, the first conductive pad CP1 may be connected to a first lower source/drain pattern LSD1 through a first lower active contact LAC1 and the lower via LVI. In addition, the second conductive pad CP2 may be connected to a second lower source/drain pattern LSD2 through a second lower active contact LAC2 and the lower via LVI.

For example, the first voltage V1 described with reference to FIGS. 4 and 5 may be applied to the upper via UVI and the upper wire UMI connected to a first upper active contact UAC1 in order to measure electrical characteristics of a transistor of the upper active region UAR and to analyze whether or not peripheral components are connected. In addition, the second voltage V2 described with reference to FIGS. 4 and 5 may be applied to the upper wire UMI and the upper via UVI connected to a second upper active contact UAC2. The third voltage V3 described with reference to FIGS. 4 and 5 may be applied to the upper wire UMI and the upper via UVI connected to the gate electrode GE. As described with reference to FIGS. 4 and 5, the electrical characteristics of the transistor of the upper active region UAR may be measured, and whether or not the peripheral components are connected may be confirmed by applying the above voltages.

For example, the first voltage V1 described with reference to FIGS. 4 and 5 may be applied to the first conductive pad CP1 connected to the first lower active contact LAC1 in order to measure electrical characteristics of a transistor of the lower active region LAR and to analyze whether or not peripheral components are connected. In addition, the second voltage V2 described with reference to FIGS. 4 and 5 may be applied to the second conductive pad CP2 connected to the second lower active contact LAC2. The third voltage V3 described with reference to FIGS. 4 and 5 may be applied to the upper wire UMI and the upper via UVI connected to the gate electrode GE. As described with reference to FIGS. 4 and 5, the electrical characteristics of the transistor of the lower active region LAR may be measured, and whether or not the peripheral components are connected may be confirmed by applying the above voltages.

Since wires of the backside metal layer BSM connected to the lower active region LAR are buried in the lower interlayered insulating layer 210, the electrical characteristics of the transistor of the lower active region LAR and whether or not the peripheral components are connected cannot be measured in the measuring method for the transistor of the upper active region UAR described above. However, the electrical characteristics of the transistor of the lower active region LAR and whether or not the peripheral components are connected may be measured even on a front of the semiconductor device by introducing the first conductive pad CP1 and the second conductive pad CP2. Accordingly, analysis reliability of the semiconductor device may be improved.

In an embodiment of the disclosure, unlike what is described with reference to FIG. 23, the first conductive pad CP1 and the second conductive pad CP2 may be buried in the lower interlayered insulating layer 210. The first conductive pad CP1 may at least partially penetrate the lower interlayered insulating layer 210, and may be connected to the backside power rail MPR under the first lower source/drain pattern LSD1. The second conductive pad CP2 may at least partially penetrate the lower interlayered insulating layer 210, and may be connected to the backside power rail MPR under the second lower source/drain pattern LSD2.

According to the disclosure, a conductive pad may be connected to a backside power rail connected to a measurement transistor in order to analyze electrical characteristics of the measurement transistor and whether or not peripheral components are connected. A current applied from a BEOL may be stably transferred to the measurement transistor, a backside conductive structure, the backside power rail and the conductive pad by applying a first voltage (for example, a ground voltage) to the conductive pad. Accordingly, according to the disclosure, the electrical characteristics of the measurement transistor may be analyzed in a structure in which power is supplied through the backside conductive structure to the measurement transistor. In addition, according to the disclosure, a noise of an analysis data may be reduced in the above method. Accordingly, analysis reliability of a semiconductor device may be improved.

The above description of example embodiments of the disclosure provides an example for description of the disclosure. Therefore, the disclosure is not limited to the above embodiments, and it is obvious that various modifications and changes such as combining the above embodiments may be made by those skilled in the art within the technical spirit of the disclosure.

What is claimed is:

1. A semiconductor device comprising:
a power transfer network layer on a lower surface of a substrate;
a source/drain pattern on the substrate, and including a first pattern and a second pattern spaced apart from each other in a first direction parallel to an upper surface of the substrate;
a backside power rail extending along the first direction under the source/drain pattern;
a backside conductive structure between the backside power rail and the first pattern of the source/drain pattern;
an active contact on an upper surface of the second pattern of the source/drain pattern;
a first interlayered insulating layer covering an upper surface of the source/drain pattern; and
a conductive pad penetrating the first interlayered insulating layer along a direction vertical to the upper surface of the substrate, and connected to the backside power rail,
wherein the active contact is shifted from the first pattern of the source/drain pattern in the first direction.

2. The semiconductor device of claim 1, wherein an upper surface of the conductive pad is not in contact with a conductive pattern including a conductive material.

3. The semiconductor device of claim 1, wherein the conductive pad is in contact with the backside power rail.

4. The semiconductor device of claim 1, wherein the conductive pad vertically overlaps the backside power rail.

5. The semiconductor device of claim 1, wherein the conductive pad penetrates the backside power rail.

6. The semiconductor device of claim 5, wherein the conductive pad is connected to the power transfer network layer.

7. The semiconductor device of claim 1, wherein the conductive pad is connected to the first pattern of the source/drain pattern through the backside power rail and the backside conductive structure.

8. The semiconductor device of claim 1, further comprising a first active region on the substrate,
wherein the conductive pad is on the first active region.

9. The semiconductor device of claim 1, further comprising:
a first active region on the substrate; and
a dummy region adjacent to the first active region in the first direction,
wherein the conductive pad is on the dummy region.

10. A semiconductor device comprising:
a power transfer network layer on a lower surface of a substrate;
a source/drain pattern being on the substrate, and including a first pattern and a second pattern spaced apart from each other in a first direction parallel to an upper surface of the substrate;
a backside power rail extending along the first direction under the source/drain pattern;
a backside conductive structure between the backside power rail and the first pattern of the source/drain pattern;
an active contact on an upper surface of the second pattern of the source/drain pattern;
a first interlayered insulating layer covering an upper surface of the source/drain pattern; and
a conductive pad penetrating the first interlayered insulating layer along a direction vertical to the upper surface of the substrate, and connected to the backside power rail,
wherein the active contact is shifted from the backside conductive structure in the first direction.

11. The semiconductor device of claim 10, wherein an upper surface of the conductive pad is not in contact with a conductive pattern including a conductive material.

12. The semiconductor device of claim 10, wherein the conductive pad penetrates the backside power rail, and is connected to the power transfer network layer.

13. The semiconductor device of claim 10, further comprising a channel pattern between the first pattern and the second pattern of the source/drain pattern,
wherein the conductive pad is connected to the active contact through the backside power rail, the backside conductive structure, the first pattern of the source/drain pattern, the channel pattern, and the second pattern of the source/drain pattern.

14. A semiconductor device comprising:
a power transfer network layer on a lower surface of a substrate;
a source/drain pattern on the substrate;
a backside power rail extending under the source/drain pattern along a first direction parallel to an upper surface of the substrate;
a backside conductive structure between the backside power rail and the source/drain pattern;
an interlayered insulating layer covering an upper surface of the source/drain pattern; and
a conductive pad penetrating the interlayered insulating layer along a direction vertical to the upper surface of the substrate, and connected to the backside power rail,
wherein an upper surface of the conductive pad is not in contact with a conductive pattern including a conductive material.

15. The semiconductor device of claim 14, wherein the source/drain pattern is a lower source/drain pattern,
further comprising an upper source/drain pattern spaced apart from the lower source/drain pattern in the direction vertical to the upper surface of the substrate.

16. The semiconductor device of claim 14, wherein the source/drain pattern comprises a first pattern and a second pattern spaced apart from each other in the first direction,
wherein the backside conductive structure is on or under the first pattern of the source/drain pattern, and
wherein the conductive pad is connected to the first pattern of the source/drain pattern through the backside power rail and the backside conductive structure.

17. The semiconductor device of claim 16, further comprising an active contact on an upper surface of the second pattern of the source/drain pattern,
wherein the active contact is shifted from the first pattern of the source/drain pattern in the first direction.

18. The semiconductor device of claim 16, further comprising an active contact on an upper surface of the second pattern of the source/drain pattern,
wherein the active contact is shifted from the backside conductive structure in the first direction.

19. The semiconductor device of claim 14, wherein the conductive pad penetrates the backside power rail, and is connected to the power transfer network layer.

20. The semiconductor device of claim 14, wherein an upper surface of the conductive pad is completely covered by an insulating layer including an insulating material.
